(19) United States
(12) Patent Application Publication
(10) Pub. No.: US 2018/0239208 A1
(43) Pub. Date: Aug. 23, 2018

(54) PIXEL STRUCTURES, ARRAY SUBSTRATES AND LIQUID CRYSTAL DISPLAY PANELS

(71) Applicant: Shenzhen China Star Optoelectronics Technology Co., Ltd., Shenzhen (CN)

(72) Inventor: Lixuan CHEN, Shenzhen (CN)

(73) Assignee: Shenzhen China Star Optoelectronics Technology Co., Ltd., Shenzhen, Guangdong (CN)

(21) Appl. No.: 15/511,241

(22) PCT Filed: Mar. 6, 2017
(86) PCT No.: PCT/CN2017/075789

§ 371 Date: Mar. 15, 2017

(30) Foreign Application Priority Data
Feb. 23, 2017 (CN) 201710099058.X

(51) Int. Cl. G02F 1/1362; G02F 1/1343; G02F 1/1335; G02F 1/1368; H01L 27/12

(52) U.S. Cl. CPC G02F 1/136286; G02F 1/134309; G02F 1/133512; G02F 2201/123; H01L 27/124; G02F 2201/121; G02F 1/1368

(57) ABSTRACT

The present disclosure relates to a pixel structure including a plurality of scanning lines, a plurality of data lines, and at least one pixel cell defined by the perpendicularly intersected the scanning lines and the data lines. The pixel cell includes a pixel driving device, common electrode lines, and at least one pixel electrode. wherein the common electrode lines and the pixel electrode are configured to be at different layers. The pixel electrode includes a display region and a non-display region surrounding the display region. Positive projections of the common electrode lines with respect to the pixel electrode are within the non-display region, and a storage capacitor is formed between the common electrode lines and the non-display region of the pixel electrode. The present disclosure further relates to an array substrate and a liquid crystal display panel including the pixel structure.

### BACKGROUND OF THE INVENTION

### 1. Field of the Invention

The present disclosure relates to liquid crystal display technology, and more particularly to a pixel structure, and further relates to an array substrate and a liquid crystal display panel including the pixel structure.

### 2. Discussion of the Related Art

With the evolution of the display technology, liquid crystal display (LCD) has recently become a most popular display product. Wherein vertical alignment (VA) type LCD has become the main product in the market due to great viewing angle and high brightness. Currently, with the high-definition demanding by the customer, the LCD with much higher brightness needs to be developed. High brightness means in the case of the white screen brightness does not decrease, to lower the optical leakage of the LCD black screen when the backlight turns on. This optical leakage depends on the backlight design, and also depends on the LCD design and polarizer design. Wherein the pixel structure in the cell has a significant influence on the pixel optical leakage.

The pixel structure mainly includes the pixel electrode and the common electrode, and the storage capacitor is formed at the overlap part of the pixel electrode and the common electrode. Usually, the pixel electrode and the common electrode are made from transparent conductive material. The common electrode is arranged under the pixel electrode and has an insulating layer therebetween. The common electrode includes transverse electrode lines and longitudinal electrode lines. The transverse electrode lines and the longitudinal electrode lines are perpendicularly disposed with each other, and the intersection of the transverse electrode lines and the longitudinal electrode lines is within the display region. The pixel structure described above may produce optical leakage, this optical leakage is mainly due to a part of the transmit light of the polarized light undergoes a certain deflection in the polarization direction after passing through a metal circuit element (for example, the transverse electrode line and the longitudinal electrode line of the common electrode). Specifically, at the position where the transverse electrode lines intersects with the longitudinal electrode lines, the angle formed by the transverse electrode lines and the longitudinal electrode lines is an arc angle (In the structural design, the angle is designed as a right angle, but due to the limitations of the manufacturing process, the actual manufacturing angle is not a strict right angle but an arc angle). For the incident polarized light, the non-horizontal/vertical metal corner or metal edge may have an impact on the polarization, causing a similar diffraction phenomenon, such that the direction of a part of the polarized light changes, which leads to the optical leakage under the screen. This optical leakage also occurs at the position where the common electrode intersects with the edge of the pixel electrode. Therefore, by eliminating the optical leakage due to the common electrode influence on the light, the higher brightness may be obtained.

### SUMMARY

The present disclosure provides a pixel structure to effectively reduce optical leakage and to enhance brightness.

In one aspect, a pixel structure including: a plurality of scanning lines and a plurality of data lines, wherein the scanning lines and the data lines intersect with each other to define a pixel cell, and the pixel cell comprises: a pixel driving device, common electrode lines and at least one pixel electrode, and the pixel electrode electrically connects to the scanning lines and the data lines via the pixel driving device, wherein the common electrode lines and the pixel electrode are configured to be at different layers, and the pixel electrode comprises a display region and a non-display region surrounding the display region; positive projections of the common electrode lines with respect to the pixel electrode are within the non-display region, and a storage capacitor is formed between the common electrode lines and the non-display region of the pixel electrode.

Wherein the positive projections of the common electrode lines with respect to the pixel electrode are within the non-display region, and are arranged on a first side and a third side of the display region, the first side is opposite to the third side, wherein the common electrode lines extend along a longitudinal direction of the scanning lines.

Wherein the positive projections of the common electrode lines with respect to the pixel electrode are within the non-display region, and are arranged on a second side and a fourth side of the display region, the second side is opposite to the fourth side, wherein the common electrode lines extend along a longitudinal direction of the data lines.

Wherein the positive projections of the common electrode lines with respect to the pixel electrode are within the non-display region, and are arranged on the first side, the second side, the third side and the fourth side of the display region, wherein the common electrode lines having the positive projections on the first side and the third side of the display region extend along a longitudinal direction of the scanning lines, and the common electrode lines having the positive projections on the second side and the fourth side of the display region extend along a longitudinal direction of the data lines.

Wherein the pixel driving device is a thin film transistor.

Wherein the display region of the pixel electrode includes: a horizontal trunk and a vertical trunk, wherein the horizontal trunk and the vertical trunk perpendicularly intersect with each other at a center, four sub-regions are equally defined by the perpendicularly intersected horizontal trunk and the vertical trunk, and the four sub-regions comprise a plurality of branches, wherein one end of each of the branches connects to the horizontal trunk or the vertical trunk, and the other end of the branches connects to the non-display region of the pixel electrode, a gap is formed between any two adjacent branches.

Wherein the display portion of the pixel electrode is symmetrical with respect to the horizontal trunk along a top-down direction, and is symmetrical with respect to the vertical trunk along a left-right direction.

Wherein an angle formed by the branches and the horizontal trunk and the angle formed by the branches and the vertical trunk equal to 45 degrees.

In another aspect, an array substrate includes a glass substrate and a pixel structure array arranged on the glass substrate, wherein the pixel structure is the pixel structure described above.

In another aspect, a liquid crystal panel which includes: a color film substrate, an array substrate arranged opposite to the color film substrate, and a plurality of liquid crystal molecules arranged between the color film substrate and the array substrate, wherein the array substrate adopts the array substrate described above.

In view of the above, the pixel structure, the corresponding array substrate and the liquid crystal display panel provided in the present disclosure, the common electrode lines of the pixel structure are arranged within the non-display region, such that optical leakage caused by the common electrode lines diffracting an incident polarized light may be avoided, and may effectively reduce optical leakage of the pixel structure, and enhance liquid crystal display brightness.

### BRIEF DESCRIPTION OF THE DRAWINGS

FIG. 1 is a schematic view of a pixel structure in accordance with one embodiment in the present disclosure.

FIG. 2 is an example illustrating positive projections on at least one pixel electrode of common electrode lines in accordance with one embodiment in the present disclosure.

FIG. 3 is an example of the positive projections on the pixel electrode of the common electrode lines in accordance with another embodiment in the present disclosure.

FIG. 4 is an example of the positive projections on the pixel electrode of the common electrode lines in accordance with another embodiment in the present disclosure.

FIG. 5 is a schematic view of an array substrate in accordance with one embodiment in the present disclosure.

FIG. 6 is a schematic view of a liquid crystal display panel in accordance with one embodiment in the present disclosure.

### DETAILED DESCRIPTION OF THE EMBODIMENTS

To clarify the purpose, technical solutions, and the advantages of the disclosure, embodiments of the invention will now be described more fully hereinafter with reference to the accompanying drawings, in which embodiments of the invention are shown. The figure and the embodiment described according to figure are only for illustration, and the present disclosure is not limited to these embodiments.

In the following description, in order to avoid the known structure and/or function unnecessary detailed description of the concept of the invention result in confusion, well-known structures may be omitted and/or functions described in unnecessary detail.

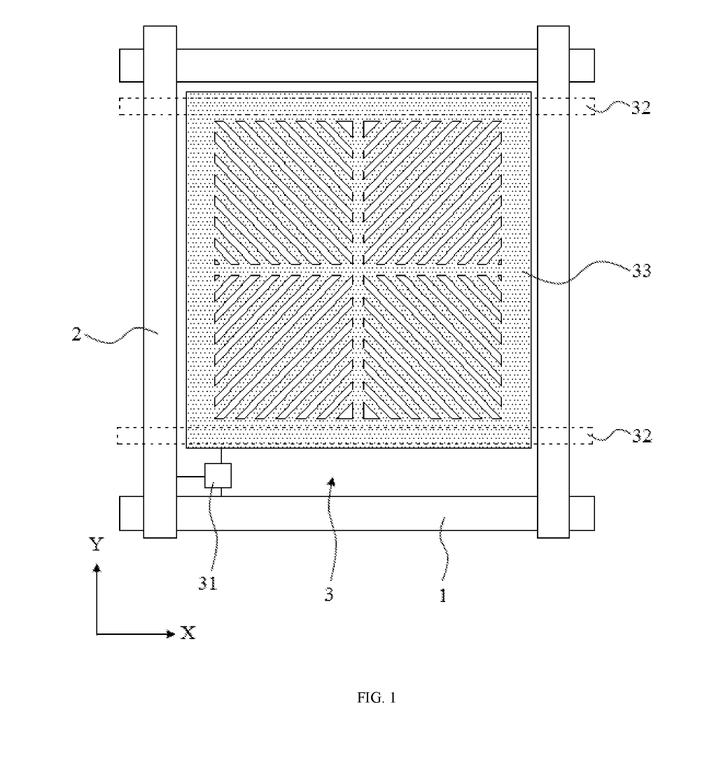

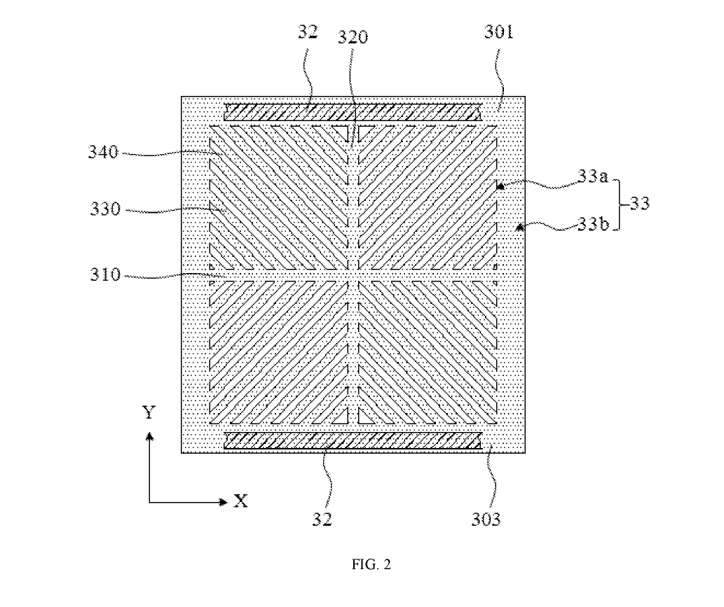

FIG. 1 is the schematic view of a pixel structure of one embodiment. As shown in FIG. 1, the pixel structure includes: a plurality of scanning lines 1, a plurality of data lines 2, a pixel cell 3 defined by the perpendicularly intersected scanning lines 1 and data lines 2, and the pixel cell 3 includes: a pixel driving device 31, common electrode lines 32 and at least one pixel electrode 33. The pixel electrode 33 electrically connects to the scanning lines 1 and the data lines 2 via the pixel driving device 31. Specifically, the pixel driving device 31 is a thin film transistor. A gate of the thin film transistor electrically connects to the scanning lines 1, a source of the thin film transistor electrically connects to the data lines 2, and a drain of thin film transistor electrically connects to the pixel electrode 33.

Wherein, the common electrode lines 32 and the pixel electrode 33 are configured to be at different layer structure (As the dotted line shown in FIG. 1, the common electrode lines 32 is configured under the pixel electrode 33). As shown in FIG. 2, the pixel electrode 33 includes: a display region 33a and a non-display region 33b surrounding the display region 33a, and positive projections of the common electrode lines 32 with respect to the pixel electrode 33 are within the non-display region 33b, and a storage capacitor is formed between the common electrode lines 32 and the non-display region 33b of the pixel electrode 33.

As provided in the pixel structure, the common electrode lines 32 are arranged in the non-display region 33b such that optical leakage caused by the common electrode lines 32 diffracting an incident polarized light may be avoided, and may effectively reduce optical leakage of the pixel structure, and enhance liquid crystal display brightness.

In one embodiment, as shown in FIG. 2, the positive projections of the common electrode lines 32 with respect to the pixel electrode 33 are within the non-display region 33b, and are arranged on a first side 301 and a third side 303 of the display region 33a, and the first side 301 is opposite to the third side 303. Wherein the common electrode lines 33 extend along a longitudinal direction (X direction in the FIG) of the scanning lines 1.

In one embodiment, as shown in FIG. 3, the positive projections of the common electrode lines 32 with respect to the pixel electrode 33 are within the non-display region 33b, and are arranged on a second side 302 and a fourth side 304 of the display region 33a, and the second side 302 is opposite to the fourth side 304. Wherein the common electrode lines 32 extend along a longitudinal direction (Y direction in the FIG) of the data lines 2.

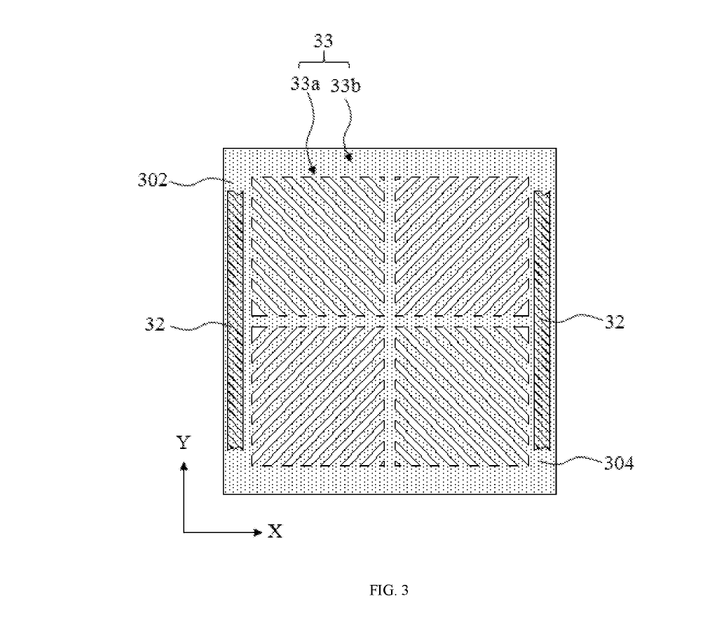

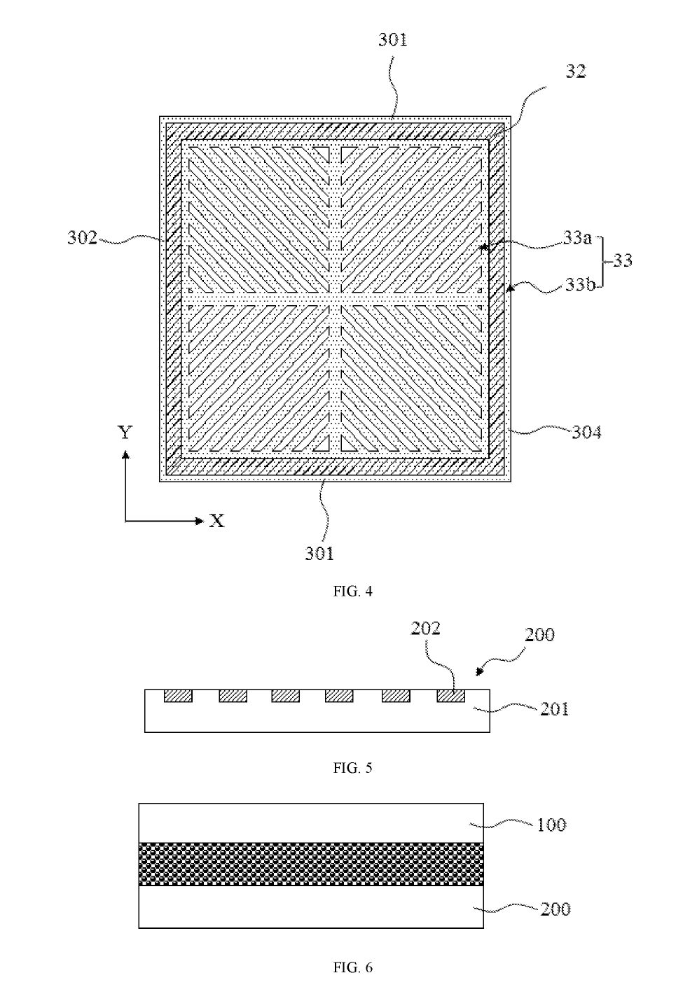

Further, in one embodiment, as shown in FIG. 4, the positive projections of the common electrode lines 32 with respect to the pixel electrode 33 are within the non-display region 33b, and are arranged on the first side 301, the second side 302, the third side 303 and the fourth side 304 of the display region 33a. The common electrode lines 32 having the positive projections on the first side 301 and the third side 303 of the display region 33a extend along a longitudinal direction (X direction in the FIG) of the scanning lines 1, and the common electrode lines 32 having the positive projections on the second side 302 and the fourth side 304 of the display region 33a extend along a longitudinal direction (Y direction in the FIG) of the data lines 2.

Referring to FIG. 2 and FIG. 3, the display region 33a of the pixel electrode 33 includes: a horizontal trunk 310 and a vertical trunk 320, wherein the horizontal trunk 310 and the vertical trunk 320 perpendicularly intersect with each other at a center, four sub-regions are equally defined by the perpendicularly intersected horizontal trunk 310 and the vertical trunk 320, and the four sub-regions comprise a plurality of branches 330, wherein one end of each of the branches connects to the horizontal trunk 310 or the vertical trunk 320, and the other end of the branches connects to the non-display region 33b of the pixel electrode 33, a gap 340 is formed between any two adjacent branches 330. Wherein, the display region 33a of the pixel electrode 33 is symmetrical with respect to the horizontal trunk 310 along a top-down direction, and is symmetrical with respect to the vertical trunk 320 along a left-right direction, and the display region 33a of the pixel electrode 33 has a “*” shape contour throughout the display region 33a.

In one embodiment, an angle formed by the branches and the horizontal trunk and the angle formed by the branches and the vertical trunk equal to 45 degrees, while in another embodiment, the angle between the branches 330 and the horizontal trunk 310 and angle between the vertical trunk 320 may equal to another degrees.

Referring to FIG. 5 and FIG. 6, this embodiment further provides an array substrate and a liquid crystal display panel including the array substrate. The liquid crystal display panel includes the array substrate 200 and a color film substrate 100 arranged opposite to the array substrate 200, and a plurality of liquid crystal molecules are arranged between the color film substrate 100 and the array substrate 200.

The array substrate 200 includes: a glass substrate 201 and the pixel structure 202 array arranged on the glass substrate 201, and the pixel structure 202 adopts the pixel structure provided in the embodiment of present disclosure. A black matrix is configured on the color film substrate 100. In the liquid crystal display panel, the black matrix relatively blocks the non-display region of the pixel structure, i.e., the non-display region 33b of the pixel electrode 33 and the common electrode lines are configured under the black matrix.

In summary, the pixel structure, the corresponding array substrate and the liquid crystal display panel provided in the present disclosure, the common electrode lines of the pixel structure are arranged within the non-display region, such that optical leakage caused by the common electrode lines diffracting an incident polarized light may be avoided, and may effectively reduce optical leakage of the pixel structure, and enhance liquid crystal display brightness.

It should be noted that the relational terms herein, such as “first” and “second”, are used only for differentiating one entity or operation, from another entity or operation, which, however do not necessarily require or imply that there should be any real relationship or sequence. Moreover, the terms “comprise”, “include” or any other variations thereof are meant to cover non-exclusive including, so that the process, method, article or device comprising a series of elements do not only comprise those elements, but also comprise other elements that are not explicitly listed or also comprise the inherent elements of the process, method, article or device. In the case that there are no more restrictions, an element qualified by the statement “comprises a . . . ” does not exclude the presence of additional identical elements in the process, method, article or device that comprises the said element.

It is believed that certain improvements and modifications may be made by those skilled in the art without departing from the principles of the present application, and such improvements and modifications shall be regarded as the scope of the present application.

What is claimed is:

1. A pixel structure, comprising:
a plurality of scanning lines and a plurality of data lines, wherein the scanning lines and the data lines intersect with each other to define a pixel cell, and the pixel cell comprises: a pixel driving device, common electrode lines and at least one pixel electrode, and the pixel electrode electrically connects to the scanning lines and the data lines via the pixel driving device, wherein the common electrode lines and the pixel electrode are configured to be at different layers, and the pixel electrode comprises a display region and a non-display region surrounding the display region;
positive projections of the common electrode lines with respect to the pixel electrode are within the non-display region, and a storage capacitor is formed between the common electrode lines and the non-display region of the pixel electrode.

2. The pixel structure according to claim 1, wherein the positive projections of the common electrode lines with respect to the pixel electrode are within the non-display region, and are arranged on a first side and a third side of the display region, the first side is opposite to the third side, wherein the common electrode lines extend along a longitudinal direction of the scanning lines.

3. The pixel structure according to claim 1, wherein the positive projections of the common electrode lines with respect to the pixel electrode are within the non-display region, and are arranged on a second side and a fourth side of the display region, the second side is opposite to the fourth side, wherein the common electrode lines extend along a longitudinal direction of the data lines.

4. The pixel structure according to claim 1, wherein the positive projections of the common electrode lines with respect to the pixel electrode are within the non-display region, and are arranged on a first side, a second side, a third side and a fourth side of the display region, wherein the common electrode lines having the positive projections on the first side and the third side of the display region extend along a longitudinal direction of the scanning lines, and the common electrode lines having the positive projections on the second side and the fourth side of the display region extend along a longitudinal direction of the data lines.

5. The pixel structure according to claim 1, wherein the display region of the pixel electrode comprises:
a horizontal trunk and a vertical trunk, wherein the horizontal trunk and the vertical trunk perpendicularly intersect with each other at a center;
four sub-regions are equally defined by the perpendicularly intersected horizontal trunk and the vertical trunk, and the four sub-regions comprise a plurality of branches, wherein one end of each of the branches connects to the horizontal trunk or the vertical trunk, and the other end of the branches connects to the non-display region of the pixel electrode;
a gap is formed between any two adjacent branches.

6. The pixel structure according to claim 5, wherein the display portion of the pixel electrode is symmetrical with respect to the horizontal trunk along a top-down direction, and is symmetrical with respect to the vertical trunk along a left-right direction.

7. The pixel structure according to claim 6, wherein an angle formed by the branches and the horizontal trunk and the angle formed by the branches and the vertical trunk equal to 45 degrees.

8. An array substrate, comprising:
a glass substrate and a pixel structure array arranged on the glass substrate, wherein the pixel structure comprises:
a plurality of scanning lines and a plurality of data lines, wherein the scanning lines and the data lines intersect with each other to define a pixel cell, and the pixel cell comprises:
a pixel driving device, common electrode lines and at least one pixel electrode, and the pixel electrode electrically connects to the scanning lines and the data lines via the pixel driving device, wherein the common electrode lines and the pixel electrode are configured be to at different layer structure, and the pixel electrode comprises a display region and a non-display region surrounding the display region;
positive projections of the common electrode lines with respect to the pixel electrode are within the non-display region, and a storage capacitor is formed between the common electrode lines and the non-display region of the pixel electrode.

9. The array substrate according to claim 8, wherein the positive projections of the common electrode lines with respect to the pixel electrode are within the non-display region, and are arranged on a first side and a third side of the display region, the first side is opposite to the third side, wherein the common electrode lines extend along a longitudinal direction of the scanning lines.

10. The array substrate according to claim 8, wherein the positive projection of the common electrode lines with respect to the pixel electrode are within the non-display region, and are arranged on a second side and a fourth side of the display region, the second side is opposite to the fourth side, wherein the common electrode lines extend along a longitudinal direction of the data lines.

11. The array substrate according to claim 8, wherein the positive projections of the common electrode lines with respect to the pixel electrode are within the non-display region, and are arranged on a first side, a second side, a third side and a fourth side of the display region, wherein the common electrode lines having the positive projections on the first side and the third side of the display region extend along a longitudinal direction of the scanning lines, and the common electrode lines having the positive projections on the second side and the fourth side of the display region extend along a longitudinal direction of the data lines.

12. The array substrate according to claim 8, wherein the display region of the pixel electrode comprises:
a horizontal trunk and a vertical trunk, wherein the horizontal trunk and the vertical trunk perpendicularly intersect with each other at a center;
four sub-regions are equally defined by the perpendicularly intersected horizontal trunk and the vertical trunk, and the four sub-regions comprise a plurality of branches, wherein one end of each of the branches connects to the horizontal trunk or the vertical trunk, and the other end of the branches connects to the non-display region of the pixel electrode;
a gap is formed between any two adjacent branches.

13. The array substrate according to claim 12, wherein the display portion of the pixel electrode is symmetrical with respect to the horizontal trunk along a top-down direction, and is symmetrical with respect to the vertical trunk along a left-right direction.

14. The array substrate according to claim 13, wherein an angle formed by the branches and the horizontal trunk and the angle formed by the branches and the vertical trunk equal to 45 degrees.

15. A liquid crystal display panel, comprising:
a color film substrate;
an array substrate arranged opposite to the color film substrate, and a plurality of liquid crystal molecules arranged between the color film substrate and the array substrate, wherein the array substrate comprises:
a glass substrate and a pixel structure array arranged on the glass substrate, wherein the pixel structure comprises:
a plurality of scanning lines and a plurality of data lines, wherein the scanning lines and the data lines intersect with each other to define a pixel cell, and the pixel cell comprises: a pixel driving device, common electrode lines and at least one pixel electrode, and the pixel electrode electrically connects to the scanning lines and the data lines via the pixel driving device, wherein the common electrode lines and the pixel electrode are configured to be at different layer structure, and the pixel electrode comprises a display region and a non-display region surrounding the display region;
positive projections of the common electrode lines with respect to the pixel electrode are within the non-display region, and a storage capacitor is formed between the common electrode lines and the non-display region of the pixel electrode.

16. The liquid crystal display panel according to claim 15, wherein the positive projections of the common electrode lines with respect to the pixel electrode are within the non-display region, and are arranged on a first side and a third side of the display region, the first side is opposite to the third side, wherein the common electrode lines extend along a longitudinal direction of the scanning lines.

17. The liquid crystal display panel according to claim 15, wherein the positive projections of the common electrode lines with respect to the pixel electrode are within the non-display region, and are arranged on a second side and a fourth side of the display region, the second side is opposite to the fourth side, wherein the common electrode lines extend along a longitudinal direction of the data lines.

18. The liquid crystal display panel according to claim 15, wherein the positive projections of the common electrode lines with respect to the pixel electrode are within the non-display region and are on a first side, a second side, a third side and a fourth side of the display region, wherein the common electrode lines having the positive projections on the first side and the third side of the display region extend along a longitudinal direction of the scanning lines, and the common electrode lines having the positive projections on the second side and the fourth side of the display region extend along a longitudinal direction of the data lines.

19. The liquid crystal display panel according to claim 15, wherein the display region of the pixel electrode comprises:
a horizontal trunk and a vertical trunk, wherein the horizontal trunk and the vertical trunk perpendicularly intersect with each other at a center;
four sub-regions are equally defined by the perpendicularly intersected horizontal trunk and the vertical trunk, and the four sub-regions comprise a plurality of branches, wherein one end of each of the branches connects to the horizontal trunk or the vertical trunk, and the other end of the branches connects to the non-display region of the pixel electrode;
a gap is formed between any two adjacent branches.

20. The liquid crystal display panel according to claim 19, wherein the display region of the pixel electrode is symmetrical with respect to the horizontal trunk along a top-down direction, and is symmetrical with respect to the vertical trunk along a left-right direction, wherein an angle formed by the branches and the horizontal trunk and the angle formed by the branches and the vertical trunk equal to 45 degrees.
